(19) United States
(12) Patent Application Publication
(10) Pub. No.: US 2002/0121016 A1
(43) Pub. Date: Sep. 5, 2002

(54) Microphone utilizing optical signal

(76) Inventors: Masahiko Moriguchi, Tottotri-shi (JP); Tetsuro Inoue, Tottori-shi (JP); Alexander Paritsky, Modiin (IL); Alexander Kots, Ashdod (IL)

Correspondence Address: TOWNSEND AND TOWNSEND AND CREW, LLP, TWO EMBARCADERO CENTER, EIGHTH FLOOR, SAN FRANCISCO, CA, 94111-3834, US

(21) Appl. No.: 09/799,846

(22) Filed: Mar. 5, 2001

(51) Int. Cl. H04R 31/00; H05K 3/30

(52) U.S. Cl. 29/594; 29/832

(57) ABSTRACT

Disclosed is a microphone that can be highly integrated and can be manufactured easily. A light emission element and a light-receiving element mounted on a substrate are sealed with transparent resin, a groove is formed in the sealed portion between the light emission element and the light-receiving element, an optically non-transparent substance is inserted in the groove, and the optically non-transparent substance is adhered to the groove with transparent resin. Thereby, in comparison to the conventional method of cutting the sealed portion together with the substrate, forming an optically non-transparent film on the cut surface, and reintegrating the cut areas, with the present invention, the number of the alignment processes is reduced and the extra margin for the setting process is no longer unnecessary.

### BACKGROUND OF THE INVENTION

1. Field of the Invention

The present invention relates to a microphone to be used for car telephones, mobile phones or the like, and a field of intruder detection utilizing a pressure change due to the intruder.

2. Description of the Related Art

A typical microphone utilizing optical signals is of a structure in which a light emission element and a light-receiving element mounted on a substrate are sealed with transparent resin, and an optically non-transparent film is provided between the light emission element and the light-receiving element inside the sealed portion. An optically non-transparent film is formed on the outer surface of the sealed portion with the transparent resin excluding the areas where a light exit and a light entrance are formed. A light-reflective membrane that vibrates due to sound, pressure or the like is retained by a membrane support above the light exit and the light entrance. Light from the light emission element is emitted from the light exit and reaches the light-receiving element via the light entrance.

In the sealed portion, the height of areas other than the light exit, the light entrance and the membrane support is set low such that the vibration of the membrane will not be hindered by air viscosity. When the position of the membrane shifts due to vibration, the reflection position also shifts, and the output of the light-receiving element will change. Sound, pressure or the like is detected by reading this output. This is the principle of the optical microphone.

As is described in Japanese Patent Application No. Hei 10-107427, the optically nontransparent film between the light emission element and the light-receiving element is prepared by a method comprising: a step of sealing a light emission element and a light-receiving element mounted on a substrate with a transparent resin, and cutting the sealed portion together with the substrate; a step of forming an optically nontransparent film on at least one of the cut faces; and a step of bonding and integrating the cut faces of the sealed portion of the light emission element and the sealed portion of the light-receiving element.

Film is formed on the cross-sections by deposition or the like. This film is for preventing the generation of bias components caused by light from the light emission element directly reaching the light-receiving element without passing through the membrane.

As the method described in aforementioned Japanese Patent Application No. Hei 10-107427 requires extra margin for the setting process during the step of adhesive integration, there are problems such as the degree of integration in the substrate becoming decreased and manufacturing costs becoming high. Moreover, the method is complex, as alignment is required during two steps; namely, upon cutting the sealed portion of the transparent resin and upon adhesively integrating the sealed portion of the light emission element and the sealed portion of the light-receiving element.

### BRIEF SUMMARY OF THE INVENTION

According to the present invention, the light emission element and the light-receiving element mounted on the substrate are sealed with transparent resin, a groove is formed at a prescribed position in the sealed portion between the light emission element and the light-receiving element, an optically non-transparent substance is inserted in the groove, and is adhered to the groove with transparent resin.

### BRIEF DESCRIPTION OF THE DRAWINGS

FIG. 1 shows an optical signal-utilizing microphone manufactured with the method according to an embodiment of the present invention.

Depicted in the FIGURE are a light emission element 1, light-receiving element 2, substrate 3, membrane support 4, membrane 5, optically non-transparent substance 6, light exit 7, light entrance 8, transparent resin 9, groove 10, and optically non-transparent film 11.

### DESCRIPTION OF THE PREFERRED EMBODIMENT

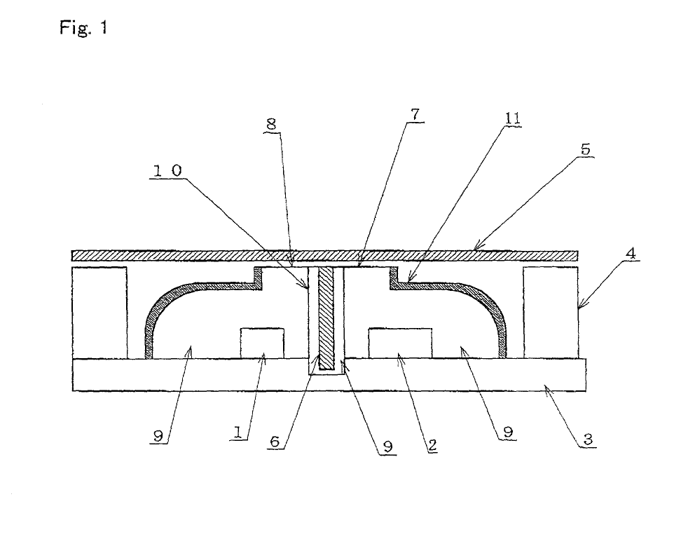

In the optical microphone according to the embodiment shown in FIG. 1, the light emission element 1 and the light-receiving element 2 mounted on the substrate 3 are sealed with the transparent resin 9, and the optically non-transparent substance 6 is provided between the light emission element and the light-receiving element inside the sealed portion. The optically non-transparent film 11 is formed on the outer surface of the transparent resin sealed portion excluding the areas where the light exit 8 and the light entrance 7 are formed. The membrane film 5 which has light reflecting properties and vibrates due to sound, pressure or the like is retained by the membrane support 4 above the light exit 8 and the light entrance 7.

Light from the light emission element 1 is emitted from the light exit 8, reflected by the membrane 5 and reaches the light-receiving element 2 via the light entrance 7. When the position of the membrane film shifts due to vibration, the reflection position also shifts, and the output of the light-receiving element will change. Sound, pressure or the like is detected by sensing this output.

In order to manufacture the aforementioned optical microphone, a light emission element such as an LED and a light-receiving element such as a photodiode are mounted on the substrate 3 such as a printed board, by die bonding or wire bonding. The light emission element 1 and light-receiving element 2 are thereafter sealed with the transparent resin 9, epoxy resin for example.

A groove is formed at a prescribed position of the sealed portion between the light emission element and light-receiving element using a device such as a dicing saw or wire saw. In FIG. 1 illustrating the embodiment, although the groove extends to the inside of the substrate in order to simplify the fixation of the foil, the groove does not have to extend to the inside of the substrate. Alignment is conducted upon forming the groove. Further, the groove width is determined by the thickness of the dicing saw blade or the wire diameter of the wire saw, and a groove of a width of roughly 50 micrometers can easily be formed.

The optically non-transparent substance 6, metal foil or resin foil for example, is inserted in this groove and sealed with the transparent resin 9 such as epoxy resin or the like. For instance, metal foil, such as a 10 micrometers-thick stainless foil, is commercially available and can easily be obtained.

According to the present invention, the extra margin for the setting process during the step of adhesive integration in the aforementioned Japanese Patent Application No. Hei 10-107427 is no longer necessary, and the degree of integration will increase. In addition, although alignment must be conducted twice in Japanese Patent Application No. Hei 10-107427, only a single alignment is necessary for forming the groove with the present invention, thereby simplifying the process.

What is claimed is:

1. A manufacturing method of an optical signal-utilizing microphone comprising a light emission element, light-receiving element, a substrate for mounting these elements, and a membrane, said method comprising the steps of:
sealing said light emission element and light-receiving element mounted on said substrate with transparent resin;
forming a groove in the sealed portion between said light emission element and light-receiving element;
inserting an optically non-transparent substance in said groove; and
adhering said optically non-transparent substance to said groove with transparent resin.
